(19) United States
(12) Patent Application Publication
(10) Pub. No.: US 2009/0140148 A1
(43) Pub. Date: Jun. 4, 2009

(54) BOLOMETER AND METHOD OF MANUFACTURING THE SAME

(75) Inventors: Woo Seok Yang, Daejeon (KR); Seong Mok Cho, Daejeon (KR); Ho Jun Ryu, Seoul (KR); Sang Hoon Cheon, Daejeon (KR); Byoung Gon Yu, Daejeon (KR); Chang Auck Choi, Daejeon (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Daejeon (KR)

(21) Appl. No.: 12/181,893

(22) Filed: Jul. 29, 2008

(30) Foreign Application Priority Data
Nov. 29, 2007 (KR) 10-2007-0122577

(51) Int. Cl. H01L 27/14; H01L 21/00

(52) U.S. Cl. 250/338.4; 438/57

(57) ABSTRACT

A bolometer having decreased noise and increased temperature sensitivity and a method of manufacturing the same are provided. The bolometer has a resistive layer formed of single crystalline silicon (Si) or silicon germanium (Si₁₋ₓGeₓ, x=0.2˜0.5) having high crystallinity, such that 1/f noise can be reduced and temperature sensitivity can be significantly improved compared to a conventional amorphous silicon bolometer.

### CROSS-REFERENCE TO RELATED APPLICATION

This application claims priority to and the benefit of Korean Patent Application No. 2007-122577, filed Nov. 29, 2007, the disclosure of which is incorporated herein by reference in its entirety.

### BACKGROUND

1. Field of the Invention

The present invention relates to a bolometer and a method of manufacturing the same, and more particularly, to a bolometer in which a resistive layer is formed of single crystalline silicon (Si) or silicon germanium (Si₁₋ₓGeₓ, x=0.2˜0.5) having high crystallinity to reduce noise and enhance temperature sensitivity, and a method of manufacturing the same.

This work was supported by the IT R&D program of MIC/IITA [2006-S-054-02, Development of Ubiquitous CMOS-based MEMS multifunctional sensor].

2. Discussion of Related Art

Infrared sensors are classified into a cooled sensor operating at the temperature of liquid nitrogen, and a uncooled sensor operating at room temperature. The cooled infrared sensor is a device which detects electron-hole pairs produced when a semiconductor material having a small bandgap such as mercury-cadmium-tellurium (HgCdTe) absorbs infrared rays through a photoconductor, a photodiode or a photocapacitor. Meanwhile, the uncooled infrared sensor is a device which detects a change in electrical conductivity or capacity due to heat generated by absorbing infrared rays, and is generally classified into a pyroelectric type, a thermopile type and a bolometer type. The uncooled sensor has a lower precision in detecting infrared rays than the cooled sensor. However, since the uncooled sensor does not need a separate cooling apparatus, it has a small size, consumes less power, and is inexpensive. Thus the uncooled sensor is widely used.

Among uncooled infrared sensors, a bolometer, which is the most commonly used, detects infrared rays by detecting an increasing resistance in a metal thin film such as a titanium (Ti) thin film, or a decreasing resistance in a semiconductor thin film such as a vanadium oxide (VOₓ) thin film or an amorphous silicon (Si) thin film, due to absorption of the infrared rays. In the bolometer, a thin film resistor (a resistive layer) is formed on an insulating membrane spaced a predetermined distance apart from a substrate having an infrared detecting circuit. The reason that the membrane is spaced a predetermined distance apart from the substrate is to effectively detect heat generated during absorption of infrared rays by thermally isolating the thin film resistor from the substrate.

The insulating membrane spaced apart from the substrate is manufactured by surface micromachining technology, according to which a sacrificial layer formed of polyimide is coated on the substrate and then patterned. Then, after the insulating thin film is deposited on the patterned sacrificial layer, the sacrificial layer is selectively removed so as to form an air-gap. Here, so that the membrane having the resistor absorbs the infrared rays as much as possible, a metal reflecting layer, for example, formed of aluminum (Al) is formed on the surface of the substrate, and the air-gap is adjusted to λ/4 (herein, λ is the wavelength of infrared rays to be detected, which is generally 8˜12 μm).

A structure of the bolometer varies depending on the kind of resistor; an amorphous silicon bolometer using amorphous silicon as a resistor will now be described.

FIGS. 1A and 1B illustrate a conventional amorphous silicon bolometer.

Referring to FIG. 1A, the conventional amorphous silicon bolometer includes a substrate 122 having a detecting circuit (not illustrated), and a sensor structure 120 spaced λ/4 (λ: wavelength of infrared rays) apart from the substrate 122.

Both sides of the sensor structure 120 are fixed on the substrate 122 by means of metal posts 124. A metal pad 128 and a metal reflecting layer 126, both formed of aluminum and electrically connected with the detecting circuit (not illustrated), are disposed on the surface of the substrate 122. The sensor structure 120 includes a resistive layer 136 formed of amorphous silicon doped with impurities, an absorption layer 132 formed of a metal such as titanium (Ti) or nickel chromium (NiCr), and upper and lower insulating layers 134 and 130 formed of silicon oxide (SiO₂) or silicon nitride (Si₃N₄). Here, the absorption layer 132 is surrounded by the lower and upper insulating layers 130 and 134 to be protected. Both ends of the resistive layer 136 are connected to the detecting circuit (not illustrated) through the metal posts 124, the metal pad 128 and the metal reflecting layer 126 by means of metal electrodes 138a and 138b.

Referring to FIG. 1B, the sensor structure 120 is fixed to the substrate 122 through the metal tab 144 and the metal post 124 by means of support arms 142 connected at both ends thereof. The support arms 142 are spaced a predetermined air-gap 146 apart from the sensor structure 120 to prevent leakage of heat to the substrate from the sensor structure 120.

The performance of the bolometer depends on the sensor structure 120 and characteristics of the resistive layer 136. Particularly, the sensor structure 120 has to have high infrared absorbability, high thermal isolation and low thermal mass, in order to prevent leakage of heat generated during absorption of infrared rays to the substrate 122, and to detect the generated heat in a short time. Moreover, the resistive layer 136 has to have a high temperature coefficient of resistance (TCR) to have a large resistance change in response to temperature change, and small 1/f noise to have a small noise equivalent temperature difference (NETD). The temperature precision that is the most important performance of the infrared sensor is generally expressed as NETD.

Generally, the 1/f noise of the resistive layer occurs due to carrier trapping caused by defects in the resistive layer, and thus is reduced with increasing crystallinity in the order of amorphous, polycrystalline, and single crystalline thin films.

Thus, when a single crystalline silicon thin film, instead of an amorphous silicon thin film, is used to manufacture a bolometer, the 1/f noise is largely decreased, such that the precision with respect to the temperature sensitivity of the infrared sensor can be significantly enhanced.

However, it is impossible to directly deposit a single crystalline silicon thin film on a substrate having a complementary metal-oxide semiconductor (CMOS) detecting circuit with current technology. Accordingly, the conventional bolometer uses an amorphous or polycrystalline thin film having low crystallinity, which places a limit on the reduction of 1/f noise and enhancement of temperature sensitivity.

### SUMMARY OF THE INVENTION

The present invention is directed to a bolometer and a method of manufacturing the same, the bolometer having reduced noise and increased temperature sensitivity by forming a resistive layer of silicon (Si) or silicon germanium (Si₁₋ₓGeₓ, x=0.2˜0.5) having high crystallinity.

One aspect of the present invention provides a bolometer, including: a semiconductor substrate containing a detecting circuit therein, a reflecting layer formed on a part of a surface of the semiconductor substrate, a pair of metal pads spaced a predetermined distance apart from each other at both sides of the reflecting layer, and a sensor structure disposed on the semiconductor substrate and separated from the surface of the reflecting layer by an air-gap of a quarter infrared wavelength (λ/4), wherein the sensor structure includes a body having a resistive layer formed of single crystalline silicon (Si) or silicon germanium (Si₁₋ₓGeₓ, x=0.2˜0.5) doped with impurities disposed on the reflecting layer, and a support arm electrically connected to the metal pads outside the body.

Another aspect of the present invention provides a method of manufacturing a bolometer, including: preparing a semiconductor substrate containing a detecting circuit therein; forming a reflecting layer on a part of a surface of the semiconductor substrate, and a pair of metal pads spaced a predetermined distance apart from each other at both sides of the reflecting layer; forming a passivation layer on the surface of the semiconductor substrate including the reflecting layer and the metal pads; forming a sacrificial layer to a thickness of a quarter infrared wavelength (λ/4) on the entire surface of the semiconductor substrate including the reflecting layer, the metal pads and the passivation layer; forming a sensor structure including a resistive layer formed of single crystalline silicon (Si) or silicon germanium (Si₁₋ₓGeₓ, x=0.2˜0.5) doped with impurities on the sacrificial layer; and removing the sacrificial layer.

### BRIEF DESCRIPTION OF THE DRAWINGS

The above and other objects, features and advantages of the present invention will become more apparent to those of ordinary skill in the art by describing in detail preferred embodiments thereof with reference to the attached drawings, in which:

FIGS. 1A and 1B illustrate a conventional amorphous silicon bolometer;

FIG. 2 illustrates a bolometer according to an exemplary embodiment of the present invention;

FIG. 3 is a flowchart illustrating a method of manufacturing a bolometer according to the present invention; and

FIGS. 4A to 4J are cross-sectional views illustrating the method of manufacturing a bolometer according to the present invention.

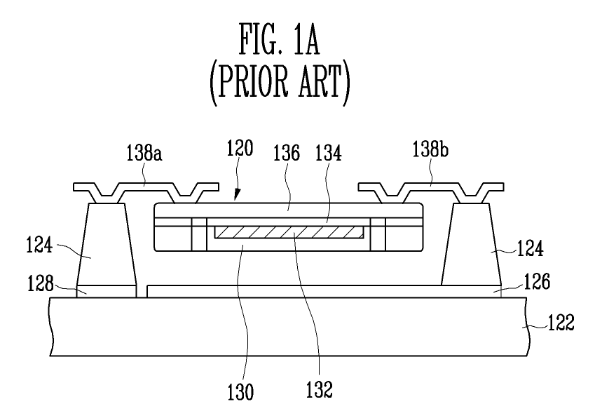

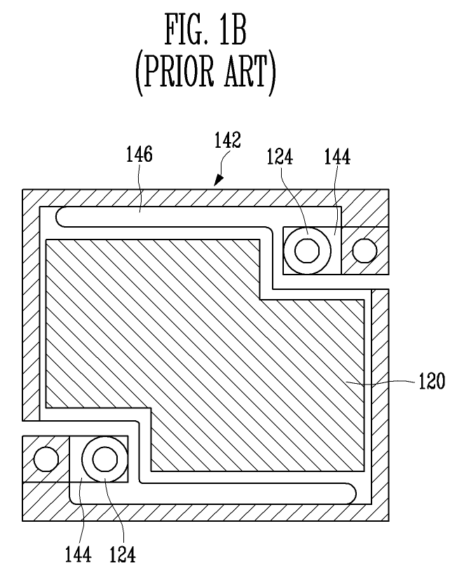

### DETAILED DESCRIPTION OF EXEMPLARY EMBODIMENTS

Hereinafter, the present invention will be described in detail with reference to the accompanying drawings. This invention may, however, be embodied in different forms and should not be construed as limited to the embodiments set forth herein. Rather, these embodiments are provided so that this disclosure will be thorough enough to enable those skilled in the art to embody and practice the invention. In the drawings, the thickness of layers and regions may be exaggerated for clarity and elements are consistently designated by the same reference numerals.

FIG. 2 illustrates a bolometer according to an exemplary embodiment of the present invention.

Referring to FIG. 2, the bolometer of the present invention includes a substrate 210 having a detecting circuit (not illustrated), a reflecting layer 214 formed at a predetermined part of the surface of the substrate 210, and a sensor structure 230 spaced an air-gap 220 of λ/4 apart from the reflecting layer 214.

The sensor structure 230 is spaced the air-gap 220 of λ/4 apart from the reflecting layer 214 for maximum absorption of infrared rays, wherein λ is the wavelength of infrared rays to be detected, and is generally 8˜12 μm.

The substrate 210 may be formed of semiconductor silicon, and the detecting circuit included in the substrate 210 is generally embodied as a CMOS circuit. Further, metal pads 212 are spaced a predetermined distance apart from the reflecting layer 214 at both sides of the reflecting layer 214 on the surface of the substrate 210. The metal pads 212 and the reflecting layer 214 may be formed of aluminum (Al), and the metal pads 212 are connected with the detecting circuit formed in the substrate 210.

The sensor structure 230 is divided into a body and a support arm. The body includes a first insulating layer 232, a resistive layer 234, a second insulating layer 236, an electrode 240, a third insulating layer 242 and an absorption layer 244, which are sequentially stacked. The support arm includes the second insulating layer 236, the electrode 240 and the third insulating layer 242, which are sequentially stacked, and is mechanically and electrically connected with the metal pads 212 formed on the surface of the substrate 210. In other words, the body is disposed to have the air-gap 220 on the reflecting layer 214, and the support arm is disposed outside the reflecting layer 214.

The first, second and third insulating layers 232, 236 and 242 are formed of aluminum oxide (Al₂O₃), each layer preferably having a thickness of 50 to 200 nm.

The resistive layer 234 is formed of single crystalline silicon (Si) or silicon germanium (Si₁₋ₓGeₓ, x=0.2˜0.5) doped with impurities, and preferably has a thickness of 100 to 150 nm.

The electrode 240 is formed of titanium nitride (TiN) or a nickel chromium (NiCr) alloy, and preferably has a thickness of 30 to 70 nm.

The absorption layer 244 is formed of titanium nitride (TiN), preferably has a sheet resistance of 377±200 Ω/cm² for maximum absorption of infrared rays, and has a thickness of 5 to 10 nm.

An auxiliary electrode 238 may be disposed between the metal pad 212 and the electrode 240 around a hole 224. This is because the thin electrode 240 is insufficient to ensure step coverage in a deep hole, such that an electrical connection between the metal pad 212 and the resistive layer 234 may be unsecure. The auxiliary electrode 238 may be formed of aluminum (Al) to a thickness of 200 to 400 nm.

That is, since the bolometer of the present invention includes the resistive layer 234 formed of single crystalline silicon (Si) or silicon germanium (Si₁₋ₓGeₓ, x=0.2˜0.5) having high crystallinity, it can considerably decrease 1/f noise and increase temperature sensitivity compared with the conventional bolometer using amorphous or polycrystalline silicon having low crystallinity.

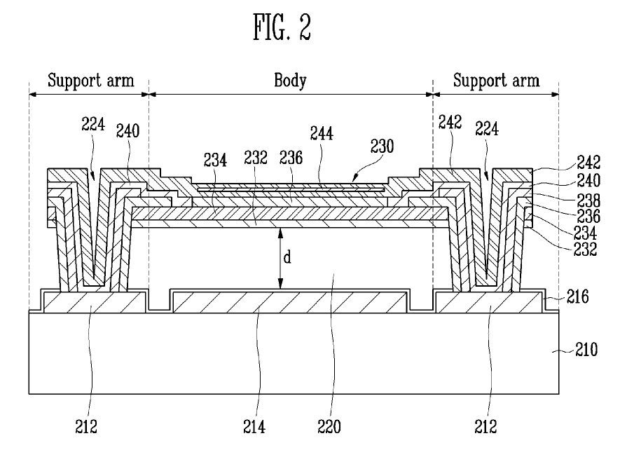

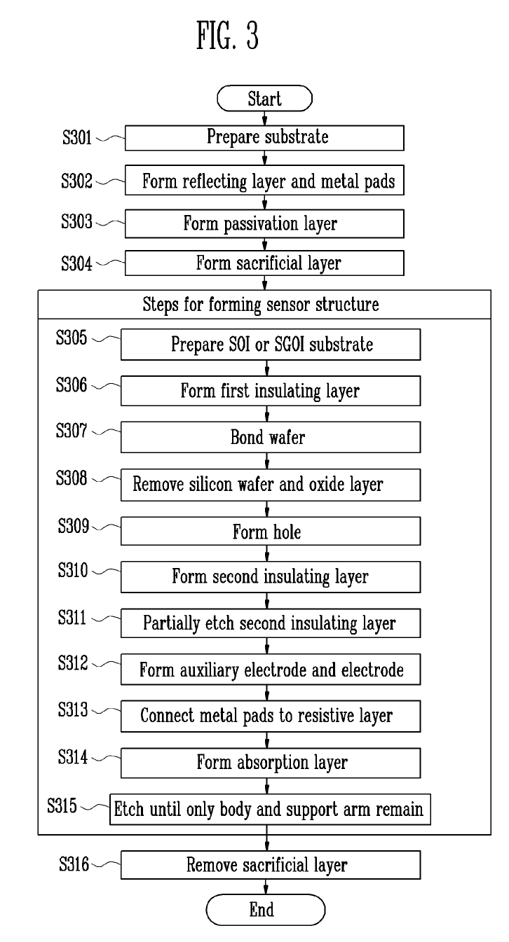

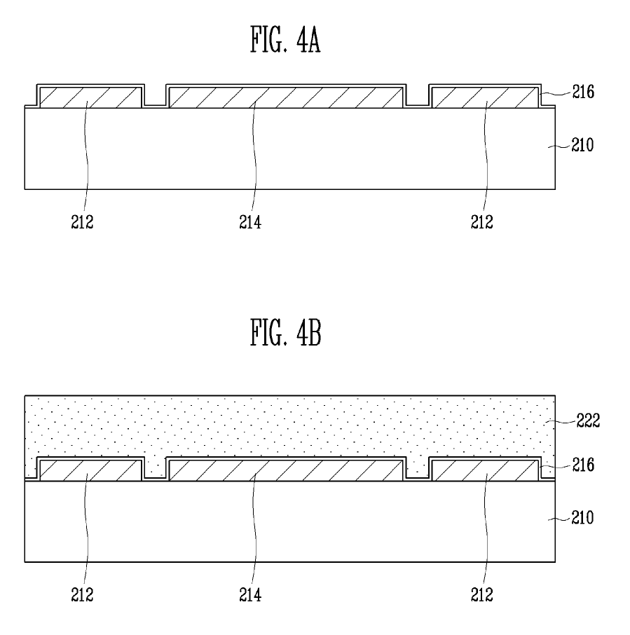

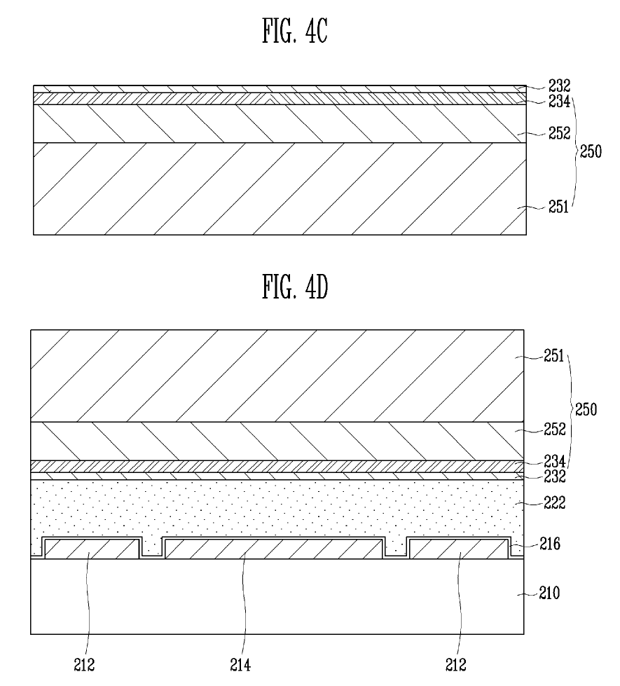

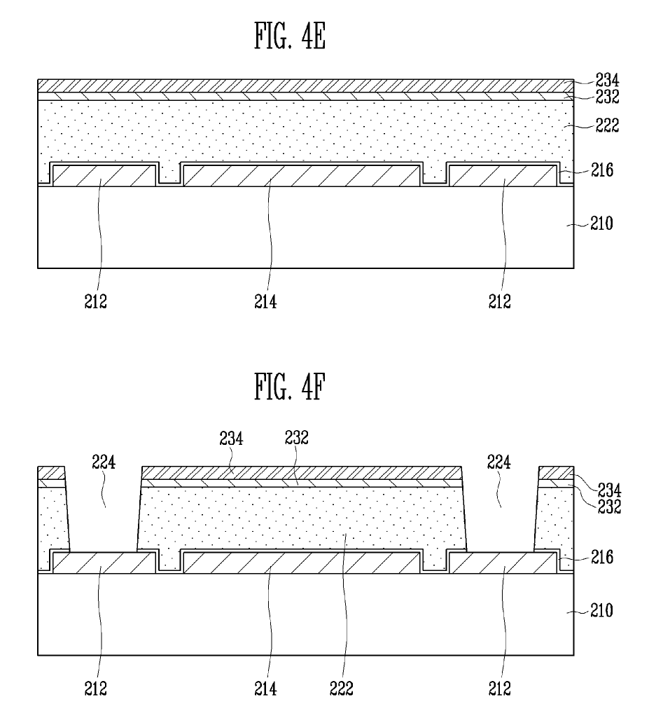

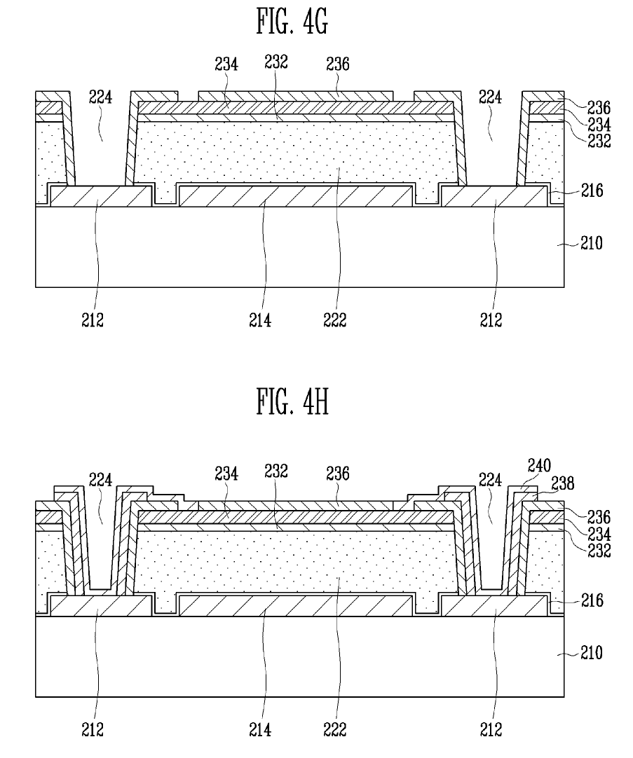

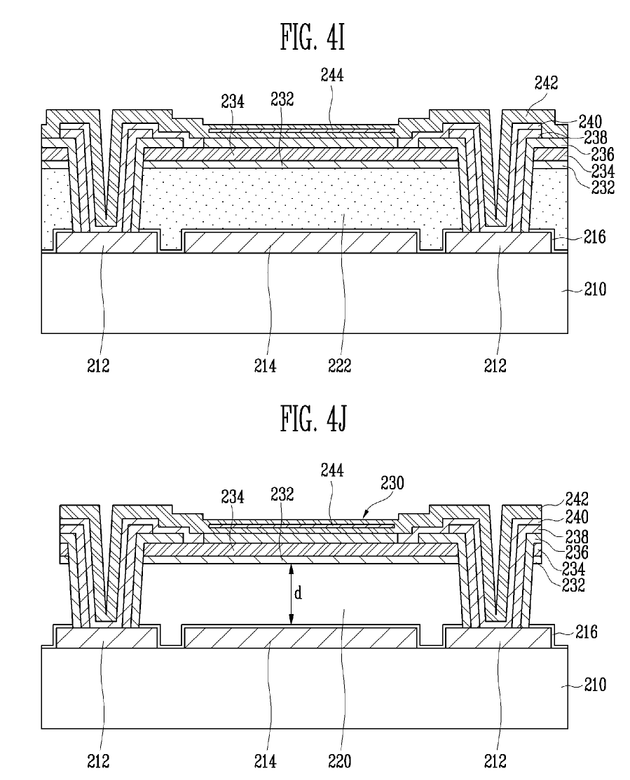

FIG. 3 is a flowchart illustrating a method of manufacturing a bolometer according to the present invention, and FIGS. 4A to 4J are cross-sectional views illustrating stages in the method of manufacturing a bolometer according to the present invention.

The method of manufacturing a bolometer shown in the flowchart of FIG. 3 will now be described with reference to FIGS. 4A to 4J.

First, referring to FIG. 4A, a substrate 210 having a CMOS detecting circuit (not illustrated) therein is prepared (S301). Then, a reflecting layer 214 is formed on the surface of the substrate 210, and metal pads 212 are formed to be spaced a predetermined distance apart from each other at both sides of the reflecting layer 214 (S302).

Here, the metal pads 212 and the reflecting layer 214 may be formed of a material having good surface reflectance and conductivity, such as aluminum (Al), and may be simultaneously formed by deposition. The metal pads 212 are electrically connected with the CMOS detecting circuit (not illustrated).

Subsequently, a passivation layer 216 is formed (S303). Here, the passivation layer 216 is preferably formed of aluminum oxide (Al₂O₃) to a thickness of 10˜50 nm. Since the passivation layer 216 is not etched with microwave plasma including fluorine (F), the passivation layer 216 prevents etching of the substrate 210 when exposed to the plasma in a following process, thereby preventing degradation of the reflectance and conductivity of the metal pads 212 and the reflecting layer 214.

Next, referring to FIG. 4B, a sacrificial layer 222 is formed on the substrate 210 (S304). Here, the sacrificial layer 222 is to be removed in the following process, the layer having adhesive strength, and preferably being formed of benzocyclobutene (BCB). In the formation of the sacrificial layer 222 using BCB, BCB is applied to a thickness (d) of λ/4 by spin-coating, and baked at 65° C. to evaporate an organic solvent. Here, λ is the wavelength of infrared rays, e.g., 8˜12 μm.

Then, referring to FIG. 4C, a silicon on insulator (SOI) or silicon-germanium on insulator (SGOI) substrate 250 is prepared (S305). The SOI or SGOI substrate 250 generally includes a double layer formed of an oxide layer 252 and a resistive layer 234 on a silicon wafer 251.

Here, the oxide layer 252 may be formed of silicon oxide (SiO₂) by thermal oxidation to a thickness of 100˜1000 nm. Further, the resistive layer 234 may be single crystalline silicon (Si) or silicon germanium (Si₁₋ₓGeₓ, x=0.2˜0.5) doped with impurities and having a thickness of 110˜200 nm.

Subsequently, a first insulating layer 232 is formed on a surface of the prepared SOI or SGOI substrate 250 (S306). Here, the first insulating layer 232 may be formed of Al₂O₃ to a thickness of 100˜200 nm.

Then, referring to FIG. 4D, the SOI or SGOI substrate 250 having the first insulating layer 232 of FIG. 4C is disposed on the substrate 210 having the adhesive sacrificial layer 222 of FIG. 4B to bond with each other (S307). Here, a thermal compression bonding process is used to bond the substrates together by applying heat and pressure thereto in a vacuum. Preferably, the process is performed at a pressure of 1.5˜2.5 bar, and a temperature of 250˜350° C., and in a vacuum of 10⁻⁴˜10⁻³ mbar. Afterwards, subsequent processes are performed at 350° C. or less to ensure thermal stability of the sacrificial layer 222.

That is, since it is impossible to directly deposit a single crystalline silicon thin film on the substrate 210 having the CMOS detecting circuit, in the present invention, the single crystalline silicon thin film 234, as described above, is separately formed on the SOI or SGOI substrate 250, and then transferred onto the substrate 210 having the CMOS detecting circuit by wafer bonding.

Next, referring to FIG. 4E, the oxide layer 252 and the silicon wafer 251 bonded to the SOI or SGOI substrate 250 are removed, such that the first insulating layer 232 and the resistive layer 234 remain on the substrate 210 (S308). Here, the removal of the silicon wafer 251 and the oxide layer 252 from the SOI or SGOI substrate 250 is performed by spray etching of a revolving substrate with an etching solution applied on the substrate surface. Such spray etching may prevent damage of the CMOS detecting circuit included in the substrate 210 likely to be caused by conventional dip etching of the substrate by dipping it into an etching solution. Preferably, as an etching solution for the silicon wafer 251, a potassium hydroxide (KOH) or tetra-methyl ammonium hydroxide (TMAH) solution is used, and as an etching solution for the oxide layer 252, a fluorine hydroxide (HF) solution is used.

Then, referring to FIG. 4F, the resistive layer 234, the first insulating layer 232, the sacrificial layer 222, and the passivation layer 216 are sequentially etched to form a hole 224 exposing the metal pad 212 (S309). Here, a three-step reactive ion etching (RIE) is used for the etching process. In a first step of the RIE process, a fluorinated etching gas such as CF₄ or SF₆ may be used to etch the sacrificial layer 234 of silicon (Si) or silicon germanium (Si₁₋ₓGeₓ, x=0.2˜0.5) and the first insulating layer 232 of aluminum oxide (Al₂O₃). In a second step, an etching gas having a mixture of a fluorinated gas and oxygen (02) may be used to etch the sacrificial layer 222 of BCB. In a third step, a fluorinated etching gas may be used to etch the passivation layer 216 of aluminum oxide (Al₂O₃). In the second and third steps of the RIE process, a part of the surface of the resistive layer 234 is simultaneously etched to a final thickness of 100·150 nm.

Subsequently, referring to FIG. 4G, while forming the hole 224, a second insulating layer 236 is formed (S310). Here, the second insulating layer 232 is formed of aluminum oxide (Al₂O₃) to a thickness of 50˜100 nm.

Subsequently, the second insulating layer 236 is partially etched to expose parts of the metal pads 212 and the sacrificial layer 234 (S311). An auxiliary electrode 238 and an electrode 240 are formed at the etched part in a following process.

Then, referring to FIG. 4H, after forming the auxiliary electrode 238 on the metal pad 212 around the hole 224, the electrode 240 is formed on the auxiliary electrode 238 and the second insulating layer 236 (S312). Preferably, the auxiliary electrode 238 is formed of aluminum (Al) to a thickness of 200˜400 nm, and the electrode 240 is formed of titanium nitride (TiN) or a nickel chromium (NiCr) alloy to a thickness of 30˜70 nm.

Subsequently, the electrode 240 is etched to connect the exposed metal pads 212 with the resistive layer 234 (S313). Thus, the second insulating layer 236 is disposed on the resistive layer 234 between the electrodes 240.

Then, referring to FIG. 41, an absorption layer 244 surrounded with a third insulating layer 242 is formed on the second insulating layer 236 between the electrodes 240 (S314). Here, the absorption layer 244 is etched to remain only on the body of the sensor structure 230, and is electrically insulated from the electrode 240 by the third insulating layer 242. Preferably, the third insulating layer 242 is formed of aluminum oxide (Al₂O₃) to a thickness of 100˜150 nm, and the absorption layer 244 is formed of titanium nitride (TiN) to have a sheet resistance of 377±200 Ω/cm², and a thickness of 5˜10 nm.

Referring to FIG. 4J, the third insulating layer 242, the second insulating layer 236, the resistive layer 234 and the first insulating layer 232 are sequentially etched to remain only the body and support arm of the sensor structure 230 (S315).

Subsequently, the sacrificial layer 222 is completely removed by microwave plasma ashing using an etching gas having a mixture of a fluorinated gas and oxygen (O₂) (S316). Here, the surface exposed to plasma when the sacrificial layer 222 is removed is protected from unnecessary etching and reactions by the passivation layer 215 of aluminum oxide (Al₂O₃) and the first, second and third insulating layers 232, 236 and 242. Accordingly, an air-gap 220 corresponding to the thickness (d) of the sacrificial layer 222 is formed between the reflecting layer 214 and the sensor structure 230.

Thus, the bolometer of the present invention manufactured through the above process includes the resistive layer 234 formed of single crystalline silicon (Si) or silicon germanium (Si₁₋ₓGeₓ, x=0.2˜0.5) having high crystallinity, which enables a dramatic reduction of 1/f noise and enhancement of temperature sensitivity compared with the conventional bolometer using amorphous or polycrystalline silicon having low crystallinity.

According to a bolometer and a method of manufacturing the same of the present invention, a resistive layer is formed of single crystalline silicon (Si) or silicon germanium (Si₁₋ₓGeₓ, x=0.2˜0.5) having high crystallinity, such that 1/f noise can be reduced and temperature sensitivity can be significantly improved.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A bolometer comprising a semiconductor substrate containing a detecting circuit therein, a reflecting layer formed on a part of a surface of the semiconductor substrate, a pair of metal pads spaced a predetermined distance apart from each other at both sides of the reflecting layer, and a sensor structure disposed on the semiconductor substrate and separated from the surface of the reflecting layer by an air-gap of a quarter infrared wavelength (λ/4), the sensor structure comprising:
a body having a resistive layer formed of single crystalline silicon (Si) or silicon germanium (Si₁₋ₓGeₓ, x=0.2˜0.5) doped with impurities disposed on the reflecting layer; and
a support arm electrically connected to the metal pads outside the body.

2. The bolometer according to claim 1, wherein the body includes a first insulating layer, the resistive layer, a second insulating layer, an electrode, an absorption layer and a third insulating layer, which are sequentially stacked, and the support arm includes the second insulating layer, the electrode and the third insulating layer, which are sequentially stacked.

3. The bolometer according to claim 2, wherein the first, second and third insulating layers are formed of aluminum oxide (Al₂O₃).

4. The bolometer according to claim 2, wherein the electrode is formed of titanium nitride (TiN) or nickel chromium (NiCr).

5. The bolometer according to claim 2, wherein the absorption layer is formed of titanium nitride (TiN).

6. The bolometer according to claim 1, wherein the infrared wavelength (λ) is 8˜12 μm.

7. The bolometer according to claim 1, further comprising:
a passivation layer formed of aluminum oxide (Al₂O₃) on the surface of the semiconductor substrate including the reflecting layer and the metal pads.

8. The bolometer according to claim 2, further comprising:
an auxiliary electrode formed between the metal pads and the electrode for stable electrical connection between the metal pads and the resistive layer.

9. A method of manufacturing a bolometer, comprising:
preparing a semiconductor substrate containing a detecting circuit therein;
forming a reflecting layer on a part of a surface of the semiconductor substrate, and a pair of metal pads spaced a predetermined distance apart from each other at both sides of the reflecting layer;
forming a passivation layer on the surface of the semiconductor substrate including the reflecting layer and the metal pads;
forming a sacrificial layer to a thickness of a quarter infrared wavelength (λ/4) on the entire surface of the semiconductor substrate including the reflecting layer, the metal pads and the passivation layer;
forming a sensor structure including a resistive layer formed of single crystalline silicon (Si) or silicon germanium (Si₁₋ₓGeₓ, x=0.2˜0.5) doped with impurities on the sacrificial layer; and
removing the sacrificial layer.

10. The method according to claim 9, wherein the passivation layer is formed of aluminum oxide (Al₂O₃).

11. The method according to claim 9, wherein the sacrificial layer is formed by applying benzocyclobutene (BCB) using spin coating.

12. The method according to claim 9, wherein the sacrificial layer is removed by a microwave plasma ashing method using an etching gas having a mixture of a fluorinated gas and oxygen (O₂).

13. The method according to claim 9, wherein the forming of the sensor structure includes:
preparing a separate silicon on insulator (SOI) or silicon-germanium on insulator (SGOI) substrate having a silicon wafer, an oxide layer, the resistive layer and a first insulating layer, which are sequentially formed;
bonding the semiconductor substrate having the sacrificial layer to the SOI or SGOI substrate;
sequentially removing the silicon wafer and the oxide layer from the SOI or SGOI substrate to leave the first insulating layer and the resistive layer on the sacrificial layer;
sequentially removing parts of the resistive layer, the first insulating layer, the sacrificial layer and the passivation layer to expose the metal pads;
forming a second insulating layer to a uniform thickness to cover the exposed parts of the resistive layer, the first insulating layer and the sacrificial layer, and removing a part of the second insulating layer to partially expose both surfaces of the resistive layer;
forming an auxiliary electrode and an electrode to electrically connect the resistive layer with the metal pads;
forming an absorption layer on the exposed second insulating layer; and
forming a third insulating layer covering the electrode, the second insulating layer and the absorption layer.

14. The method according to claim 13, wherein the semiconductor substrate having the sacrificial layer is bonded to the SOI or SGOI substrate by thermal compression bonding in a vacuum state.

15. The method according to claim 13, wherein the silicon wafer is removed from the SOI or SGOI substrate by spray etching using a potassium hydroxide (KOH) or tetra-methyl ammonium hydroxide (TMAH) solution.

16. The method according to claim 13, wherein the oxide layer is removed from the SOI or SGOI substrate by spray etching using a fluorine hydride (HF) solution.

17. The method according to claim 13, wherein all processes following bonding of the semiconductor substrate having the sacrificial layer to the SOI or SGOI substrate are performed at a temperature of 350° C. or less.
